(19) United States
(12) Patent Application Publication
(10) Pub. No.: US 2017/0139325 A1
(43) Pub. Date: May 18, 2017

(54) PHOTOSENSITIVE REFRACTIVE INDEX-ADJUSTING TRANSFER FILM

(71) Applicant: HITACHI CHEMICAL COMPANY, LTD., Tokyo (JP)

(72) Inventors: Mayumi SATO, Chiyoda-ku, Tokyo (JP); Ikuo MUKAI, Chiyoda-ku, Tokyo (JP); Tadahiro KIMURA, Chiyoda-ku, Tokyo (JP); Naoki SASAHARA, Chiyoda-ku, Tokyo (JP); Koji ABE, Chiyoda-ku, Tokyo (JP); Hideo TAKAHASHI, Chiyoda-ku, Tokyo (JP)

(21) Appl. No.: 15/323,346

(22) PCT Filed: Jul. 2, 2014
(86) PCT No.: PCT/JP2014/067661

§ 371 Date: Dec. 30, 2016

(51) Int. Cl. G03F 7/11; G03F 7/20; G03F 7/031; C08F 220/18; G03F 7/033; G03F 7/16; G03F 7/32

(52) U.S. Cl. CPC G03F 7/11; G03F 7/162; G03F 7/168; G03F 7/2002; G03F 7/32; C08F 220/18; G03F 7/033; G03F 7/031

(57) ABSTRACT

By forming a refractive index-adjusting pattern by using a photosensitive refractive index-adjusting transfer film comprising a supporting film, a photosensitive resin layer provided on the supporting film, and a high-refractive index layer provided on the photosensitive resin layer, it is possible to form easily a cured film that can attain simultaneously prevention of pattern visibility phenomenon, prevention of lowering in transmittance of a screen and protection of a sensor metal wiring.

### TECHNICAL FIELD

The present invention relates to a photosensitive refractive index-adjusting transfer film. In particular, the present invention relates to a photosensitive refractive index-adjusting transfer film that can form easily a cured film having both functions; i.e. a function as a protective film of a transparent electrode, and a function of allowing a transparent electrode pattern to be invisible or improving visibility of a touch screen.

### BACKGROUND ART

In a display of a large-sized electronic device such as PCs and TVs; a small-sized electronic device such as a car navigation, a portable phone and an electronic dictionary, an OA or FA device, a liquid crystal display device or a touch panel (touch sensor) is used. In these liquid crystal display devices or touch panels, an electrode made of a transparent electrode material is provided. As the transparent electrode material, ITO (Indium-Tin-Oxide), indium oxide or tin oxide constitutes the mainstream thereof since they exhibit high transmittance for visible rays.

As the touch panel, various types of touch panel have already been put into practical use. Since it enables finger tips to conduct multiple detection, a projected capacitive touch panel has excellent operability that it can issue complicated instructions. Due to such excellent operability, in a device having a small-sized display such as a portable phone or a portable music player, a projected capacitive touch panel has been actively used as an input device on a display screen.

In general, in a projected capacitive touch panel, in order to express two-dimensional coordinates of the X-axis and the Y-axis, plural X electrodes and plural Y electrodes that cross orthogonally the X electrodes form a two-layer structure pattern. As these electrodes, in recent years, use of conductive fibers, the representative examples of which include Ag nanowires and carbon nanotubes, has been examined. However, ITO still constitutes the mainstream of the electrode material.

Meanwhile, since a perimeter area of a touch panel is a region where no touch position can be detected, it is important to reduce the area of such perimeter area in order to improve the product value. In order to transmit detected signals of touch positions, metal wiring is required to be provided in the perimeter area. For narrowing the perimeter area, it is required to decrease the width of the metal wiring. Since conductivity of ITO is not sufficiently high, the metal wiring is made of copper, in general.

When contacting the finger tips, corrosive components such as water or salt may be invaded into the inside into a touch panel from a sensing area. If corrosive components are invaded into the inside of a touch panel, the above-mentioned metal wiring corrodes, and as a result, an electrical resistance between an electrode and a driving circuit may be increased or disconnection may occur.

A projected capacitive touch panel in which an insulating layer is formed on a metal in order to prevent corrosion of metal wiring is disclosed (Patent Document 1, for example). In this touch panel, a silicon dioxide layer is formed on a metal by plasma chemical deposition method (plasma CVD method), thereby preventing corrosion of a metal. However, this method requires a high-temperature treatment, and there are problems that usable substrates are restricted, whereby production costs are increased, or the like.

Under such circumstances, the inventors of the present invention have proposed a method in which a photosensitive layer made of a specific photosensitive resin composition is provided on a transparent substrate, and the metal wiring on the transparent substrate is protected by subjecting this photosensitive layer to light exposure and development (Patent Document 2, for example).

As mentioned above, in a projected capacitive touch panel, on a substrate, plural X electrodes and plural Y electrodes that cross orthogonally to the X electrodes made of transparent electrode materials are formed, thereby to form a transparent electrode pattern having a two-layer structure. A difference in color becomes large due to optical reflection of a part in which a transparent electrode pattern is formed and a part in which a transparent electrode pattern is not formed. As a result, when it is formed into a module, the so-called “pattern visibility phenomenon” in which a transparent electrode pattern is pictured in a screen may occur. Further, between a substrate and a transparent electrode or between a visibility improvement film (OCA: Optical Clear Adhesive) that adheres a cover glass used for forming the film into a module and a transparent electrode pattern, the intensity of reflected light is increased to lower the transmission ratio of a screen.

In order to prevent occurrence of “pattern visibility phenomenon” or lowering in transmittance, disclosed is a transparent conductive film in which an IM layer (optical adjusting layer) is provided between a substrate and a transparent electrode pattern, thereby to suppress difference in color, and as a result, pattern visibility phenomenon and lowering in transmittance of a screen (Patent Document 3, for example) are prevented.

### RELATED ART DOCUMENTS

### Patent Documents

Patent Document 1: JP-A-2011-28594

Patent Document 2: WO2013/084873

Patent Document 3: JP-A-H08-240800

### SUMMARY OF THE INVENTION

### Problems to be Solved by the Invention

However, the technique disclosed in Patent Document 3 is not sufficient in respect of preventing “pattern visibility phenomenon” and lowering in transmittance, and there is a room for further improvement. In the above-mentioned technology, there is a problem that, in order to form an IM layer, sputtering or coating by spin coating or the like is required, and in addition to the sputtering or coating, prevention of corrosion of the metal wiring in the perimeter region of a touch panel has to be conducted separately, thus leading to an increase in the number of steps.

Further, there is a problem that, even if an attempt is made to combine the technique in Patent Document 3 with the technique in Patent Document 2 regardless of an increase in number of steps; specifically, even if an attempt is made to form an IM layer on a substrate, a transparent electrode pattern on the IM layer, and to form an IM layer on the transparent electrode pattern, since the surface on which the transparent electrode pattern is not even, the IM layer cannot be formed uniformly.

An object of the present invention is to provide a photosensitive refractive index-adjusting transfer film capable of forming a cured form easily that can attain both prevention of “pattern visibility phenomenon” of a transparent electrode, lowering in transmittance of a screen and protection of a sensor metal wiring.

### Means for Solving the Problem

The inventors of the present invention made extensive studies to solve the above-mentioned problems. As a result, the inventors have found that, by forming a thin IM layer on a transparent conductive pattern by using a photosensitive refractive index-adjusting transfer film composed of a photosensitive resin layer and a high-refractive index layer, suppression of an increase in difference in color, prevention of the “pattern visibility phenomenon” and improvement of visibility of a touch screen by elimination of lowering in transmittance of a screen and prevention of corrosion of the metal wiring can be attained simultaneously. The present invention has been made based on this finding.

The specific feature of the present invention will be described below.

<1> A photosensitive refractive index-adjusting transfer film comprising a supporting film, a photosensitive resin layer provided on the supporting film, and a high-refractive index layer provided on the photosensitive resin layer.
<2> The photosensitive refractive index-adjusting transfer film according to <1>, wherein the refractive index at 633 nm of the high-refractive index layer is 1.5 to 1.9.
<3> The photosensitive refractive index-adjusting transfer film according to <1> or <2>, wherein the thickness of the high-refractive index layer is 0.05 to 1 μm.
<4> The photosensitive refractive index-adjusting transfer film according to any one of <1> to <3>, wherein the high-refractive index layer comprises zirconium oxide, titanium oxide, a compound having a triazine ring, a compound having a fluorene skeleton or a compound having an isocyanuric acid skeleton.
<5> The photosensitive refractive index-adjusting transfer film according to any one of <1> to <4>, wherein the photosensitive resin layer comprises a binder polymer, a photopolymerizable compound and a photopolymerization initiator.
<6> The photosensitive refractive index-adjusting transfer film according to <5>, wherein the photopolymerization initiator comprises an oxime ester compound.
<7> The photosensitive refractive index-adjusting transfer film according to <5> or <6>, wherein the binder polymer comprises a carboxyl group.
<8> The photosensitive refractive index-adjusting transfer film according to any one of <1> to <7>, wherein the minimum value of the visible ray transmittance at 400 to 700 nm is 90% or more.
<9> The photosensitive refractive index-adjusting transfer film according to any one of <1> to <8>, wherein the total thickness of the photosensitive resin layer and the high-refractive index layer is 30 μm or less.
<10> A method for forming a refractive index-adjusting pattern, comprising:

a step of laminating the high-refractive index layer and the photosensitive resin layer of the photosensitive refractive index-adjusting transfer film according to any one of <1> to <9> on a substrate such that the high-refractive index layer is brought into close contact with the substrate; and

a step of exposing prescribed parts of the high-refractive index layer and the photosensitive resin layer on the substrate, and removing parts other than the prescribed parts, thereby to form a refractive index-adjusting pattern.

<11> An electronic component having a refractive index-adjusting pattern that is obtained by the method according to <10>.

### Advantageous Effects of the Invention

According to the invention, it is possible to provide a photosensitive refractive index-adjusting transfer film capable of forming a cured film easily that has both a function as a protective film of a transparent electrode and a function of allowing a transparent electrode pattern to be invisible or improving visibility of a touch screen.

### BRIEF DESCRIPTION OF THE DRAWINGS

FIG. 1 is a schematic cross-sectional view showing the photosensitive refractive index-adjusting transfer film of the present invention;

FIG. 2 is a schematic cross-sectional view showing one embodiment in which the photosensitive refractive index-adjusting transfer film of the present invention is used in a substrate provided with a transparent conductive pattern; and

FIG. 3 is a schematic plan view showing an electronic component according to one embodiment of the present invention.

Hereinbelow, the mode for carrying out the present invention will be explained in detail. However, the present invention is not limited to the embodiments mentioned below. In the specification, the “(meth)acrylic acid” means an acrylic acid or a methacrylic acid, and the “(meth)acrylate” means acrylate or methacrylate corresponding thereto. The “(poly)oxyethylene chain” means an oxyethylene group or a polyoxyethylene group. The “(poly)oxypropylene chain” means an oxypropylene group or a polyoxypropylene group. The “A or B” means inclusion of either one of A and B or inclusion of both A and B.

In the specification, the “step” includes not only an independent step. That is, if a step cannot be clearly distinguished from other steps, the step is included in the “step” as long as the step attains its prescribed effects. The numerical range indicated by using “to” means a range including numerical values indicated before and after the “to” as a minimum value and a maximum value, respectively.

Further, as for the content of each component in the composition in the specification, when plural substances corresponding to these components are present in the composition, unless otherwise indicated, the content means the total amount of these plural substances in the composition. In addition, unless otherwise indicated, exemplified materials may be used singly or in combination of two or more.

### (Photosensitive Refractive Index-Adjusting Transfer Film)

The present invention provides a photosensitive refractive index-adjusting transfer film that comprises a supporting film, a photosensitive resin layer provided on the supporting film and a high-refractive index layer provided on the photosensitive layer.

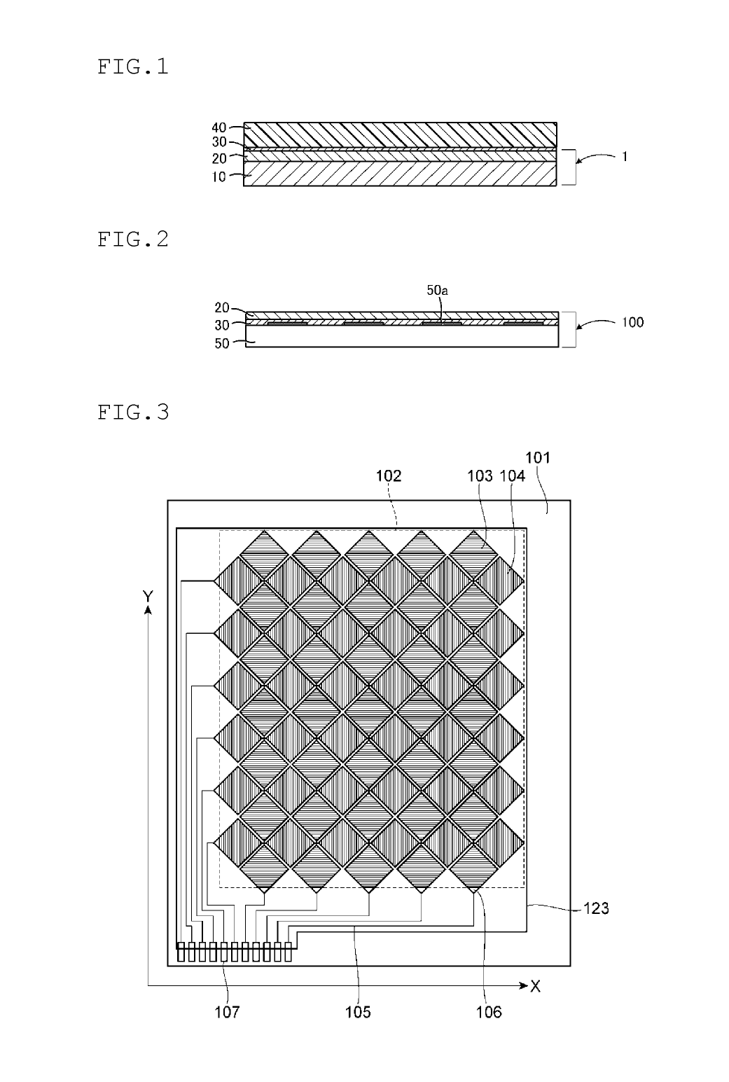

FIG. 1 is a schematic cross-sectional view showing one embodiment of the photosensitive refractive index-adjusting transfer film of the present invention. The photosensitive refractive index-adjusting transfer film 1 shown in FIG. 1 is provided with a supporting film 10, a photosensitive resin layer 20 (hereinafter often referred to as a photosensitive layer) provided on the supporting film and a high-refractive index layer 30 (hereinafter often referred to as a high-refractive layer) provided on the photosensitive resin layer. Further, the photosensitive refractive index-adjusting transfer film may include a protective film 40 provided on the side opposite to the supporting film 10 of the photosensitive layer 20, as shown in FIG. 1.

By using the above-mentioned photosensitive refractive index-adjusting transfer film, a cured film that satisfies, for example, a function of protecting the metal wiring in the perimeter of a touch panel or a transparent electrode and a function of allowing a transparent electrode pattern to be invisible or improving visibility of a touch screen can be formed simultaneously.

As the supporting film 10, a polymer film can be used. As the polymer film, polyethylene terephthalate, polycarbonate, polyethylene, polypropylene, polyethersulfone, cycloolefin polymer or the like can be given.

As for the thickness of the supporting film 10, in respect of securing coating property and suppressing lowering in resolution when irradiating active rays through the supporting film 10, the thickness is preferably 5 to 100 μm, more preferably 10 to 70 μm, further preferably 15 to 40 μm, and particularly preferably 15 to 35 μm.

### (Photosensitive Layer)

It is preferred that the photosensitive layer 20 be formed of a photosensitive resin composition comprising a binder polymer (hereinbelow, often referred to as component (A)), a photopolymerizable compound (hereinbelow often referred to as component (B)) and a photopolymerization initiator (hereinbelow often referred to as component (C)).

As the component (A), in respect of enabling patterning by alkali development, it is preferable to use a polymer having a carboxyl group.

As the component (A), a copolymer comprising constituent units derived from (meth)acrylic acid and (meth)acrylic acid alkyl ester is preferable. The copolymer mentioned above may contain, as its constituent unit, other monomers that can copolymerize with the (meth)acrylic acid and the (meth)acrylic acid alkyl ester. Specifically, (meth)acrylic acid glycidyl ester, (meth)acrylic acid benzyl ester, styrene or the like can be given.

As the above-mentioned (meth)acrylic acid ester, (meth)acrylic acid methyl ester, (meth)acrylic ethyl ester, (meth)acrylic acid butyl ester, (meth)acrylic acid 2-ethylhexyl ester, (meth)acrylic hydroxyl ethyl ester or the like can be given.

In respect of resolution, the weight-average molecular weight of the component (A) is preferably 10,000 to 200, 000, more preferably 15,000 to 150,000, further preferably 30,000 to 150,000, particularly preferably 30,000 to 100,000, with 40,000 to 100,000 being significantly preferable. Meanwhile, the weight-average molecular weight can be measured by a gel permeation method with reference to the Examples of the present specification.

The acid value of the component (A) is preferably 75 mgKOH/g or more in respect of forming a protective film having a desired shape easily by alkali development. Further, in respect of attaining both easiness in control of the shape of a protective film and rust prevention of a protective film, the acid value is preferably 75 to 200 mgKOH/g, more preferably 75 to 150 mgKOH/g, and further preferably 75 to 120 mgKOH/g. The acid value can be measured with reference to the Examples of the present specification.

In respect of further improving rust prevention properties, the hydroxyl value of the component (A) is preferably 50 mgKOH/g or less, more preferably 45 mgKOH/g or less. The hydroxyl value can be measured with reference to the Examples of the present specification.

As the component (B), a photopolymerizable compound having an ethylenically unsaturated group can be used. As the photopolymerizable compound having an ethylenically unsaturated group, a monofunctional vinyl monomer, a bifunctional vinyl monomer, or a polyfunctional vinyl monomer having at least three polymerizable ethylenically unsaturated groups can be given.

As the monofunctional vinyl monomer, those exemplified above as the monomer used for the synthesis of a copolymer that is a preferable example of the component (A) can be given.

As the bifunctional vinyl monomer, polyethylene glycol di(meth)acrylate, trimethylolpropane di(meth)acrylate, polypropylene glycol di(meth)acrylate, 2,2-bis(4-(meth)acryloxypolyethoxypolypropoxyphenyl)propane, bisphenol A diglycidyl ether di(meth)acrylate or the like can be given.

As the polyfunctional vinyl monomer having at least three ethylenically polymerizable unsaturated groups, those conventionally known in the art can be used without particular restrictions. In respect of prevention of corrosion of the metal wiring or the transparent electrode and developing property, it is preferable to use a (meth)acrylate compound having a skeleton derived from trimethylol propane such as trimethylol propane (meth)acrylate; a (meth)acrylate compound having a skeleton derived from tetramethylol methane such as tetramethylol methane tri(meth)acrylate and tetramethylol methane tetra(meth)acrylate; (meth)acrylate compound having a skeleton derived from pentaerythritol such as pentaerythritol tri(meth)acrylate and pentaerythritol tetra(meth)acrylate; a meth(acrylate) compound having a skeleton derived from dipentaerythritol such as dipentaerythritol penta(meth)acrylate and dipentaerythritol hexa(meth)acrylate; a (meth)acrylate compound having a skeleton derived from ditrimethylol propane such as ditrimethylol propane tetra(meth)acrylate; or a (meth)acrylate compound having a skeleton derived from diglycerin.

More specifically, it is preferable to include a (meth)acrylate compound having a skeleton derived from pentaerythritol, a (meth)acrylate compound having a skeleton derived from dipentaerythritol, a (meth)acrylate compound having a skeleton derived from trimethylolpropane or a (meth)acrylate compound having a skeleton derived from ditrimethylolpropane. It is more preferable to include a (meth)acrylate compound having a skeleton derived from dipentaerythritol or a (meth)acrylate compound having a skeleton derived from ditrimethylolpropane. It is further preferable to include a (meth)acrylate compound having a skeleton derived from ditrimethylolpropane.

As for the “(meth)acrylate compound having a skeleton derived from . . . ”, an explanation will be made taking as an example a (meth)acrylate compound having a skeleton derived from ditrimethylolpropane.

The (meth)acrylate having a skeleton derived from ditrimethylolpropane means an esterified product of ditrimethylolpropane and (meth)acrylic acid. The esterified product includes compounds obtained by esterifying an alkylene oxy group. It is preferred that the maximum number of ester bonds in a single molecule of the esterified product mentioned above be 4. Compounds having 1 to 3 ester bonds may be mixed.

When a monomer having at least three polymerizable ethylenically unsaturated groups in a single molecule is used in combination with a monofunctional vinyl monomer or a bifunctional vinyl monomer, although no specific restrictions are imposed on the amount ratio, in respect of improving photocurability and prevention of electrode corrosion, the amount ratio of a monomer having at least three polymerizable ethylenically unsaturated groups in a molecule is preferably 30 parts by mass or more, 50 parts by mass or more and further preferably 75 parts by mass or more, relative to 100 parts by mass of the total amount of the photopolymerizable compounds contained in the photosensitive resin composition.

As for the contents of the component (A) and the component (B), the content of the component (A) is preferably 35 to 85 parts by mass, more preferably 40 to 80 parts by mass, further preferably 50 to 70 parts by mass, and particularly preferably 55 to 65 parts by mass, relative to 100 parts by mass of the total contents of the component (A) and the component (B). In particular, in respect of maintaining pattern-forming property or transparency of a cured film, the content of the component (A) is preferably 35 parts by mass or more, more preferably 40 parts by mass or more, further preferably 50 parts by mass or more, and particularly preferably 55 parts by mass or more relative to 100 parts by mass of the total amount of the component (A) and the component (B).

As the component (C), conventionally known compounds can be used without particular restrictions as long as it is a photopolymerization initiator having high transparency. In respect of forming on a substrate a thin resin cured film (as thin as 10 μm or less) with a sufficient resolution, it is preferred that an oxim ester compound be contained.

The oxim ester compound is preferably a compound represented by the following formula (1), a compound represented by the following formula (2) or a compound represented by the following formula (3).

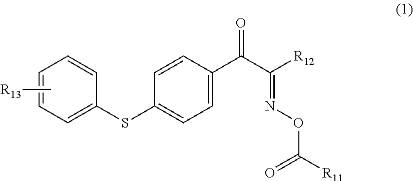

In the formula (1), it is preferred that R₁₁ and R₁₂ be independently an alkyl group having 1 to 12 carbon atoms, a cycloalkyl group having 4 to 10 carbon atoms, a phenyl group or a tolyl group. R₁₁ and R₁₂ are preferably an alkyl group having 1 to 8 carbon atoms, a cycloalkyl group having 4 to 6 carbon atoms, a phenyl group or a tolyl group, more preferably an alkyl group having 1 to 4 carbon atoms, a cycloalkyl group having 4 to 6 carbon atoms, a phenyl group or a tolyl group. R₁₃ is —H, —OH, —COON, —O(CH₂)OH, —O(CH₂)₂OH, —COO(CH₂)OH or —COO(CH₂)₂OH. R₁₃ is preferably —H, —O(CH₂)OH, —O(CH₂)₂OH, —COO(CH₂)OH or —COO(CH₂)₂OH, more preferably —H, —O(CH₂)₂OH or —COO(CH₂)₂OH.

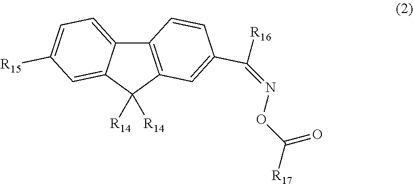

In the formula (2), R₁₄s are independently an alkyl group having 1 to 6 carbon atoms, and are preferably a propyl group.

R₁₅ is NO₂ or ArCO (wherein Ar is an aryl group). As the Ar, a tolyl group is preferable.

R₁₆ and R₁₇ are independently an alkyl group having 1 to 12 carbon atoms, a phenyl group or a tolyl group. A methyl group, a phenyl group or a tolyl group are preferable.

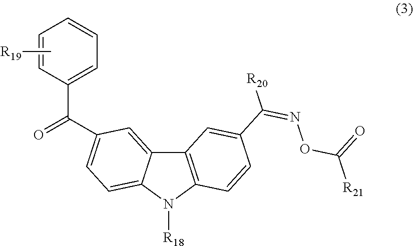

In the formula (3), R₁₈ is an alkyl group having 1 to 6 carbon atoms, with an ethyl group being preferable.

R₁₉ is an organic group having an acetal bond, and is preferably a substituent that corresponds to R₁₉ contained in a compound represented by the formula (3-1) given later.

R₂₀ and R₂₁ are independently an alkyl group having 1 to 12 carbon atoms, a phenyl group or a tolyl group. R₂₀ and R₂₁ are preferably a methyl group, a phenyl group or a tolyl group, with a methyl group being more preferable.

As the compound represented by the formula (1), a compound represented by the following formula (1-1) and a compound represented by the following formula (1-2) can be given. The compound represented by the following formula (1-1) can be commercially available as IRGACURE OXE-01 (manufactured by BASF Japan, Ltd.).

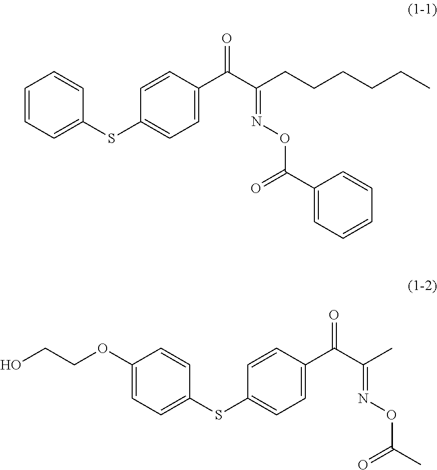 [SMILES: CCCCCC/C(=N\OC(=O)c1ccccc1)C(=O)c1ccc(Sc2ccccc2)cc1 ; CC(=O)O/N=C(\C)C(=O)c1ccc(Sc2ccc(OCCO)cc2)cc1]

As the compound represented by the above formula (2), a compound represented by the following formula (2-1) can be given. The compound represented by the following formula (2-1) can be commercially available as DFI-091 (manufactured by Daito Chemix Co., Ltd.).

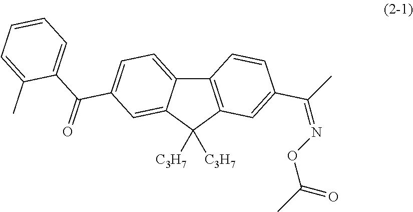

As the compound represented by the above formula (3), a compound represented by the following formula (3-1) can be given. The compound represented by the following formula (3-1) can be commercially available as Adeka Optomer-N-1919 (product name: manufactured by Adeka Corporation).

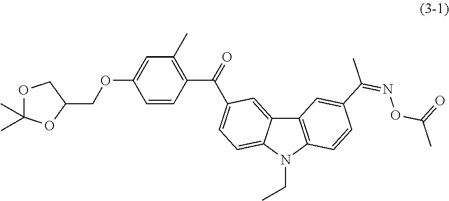 [SMILES: CCn1c2ccc(C(=O)c3ccc(OCC4COC(C)(C)O4)cc3C)cc2c2cc(/C(C)=N\OC(C)=O)ccc21]

As other oxime ester compounds, it is preferable to use a compound represented by the following formula (4) or a compound represented by the following formula (5).

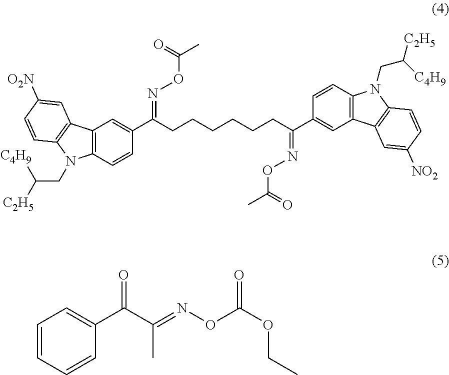

Among these, the compound represented by the above formula (1-1) is significantly preferable. Meanwhile, whether the compound represented by the above formula (1-1) is included in a cured film can be judged by checking whether heptanone and benzoic acid can be detected when the cured film is subjected to pyrolysis gas chromatography mass spectrometry. If the cured film is not subjected to a high-temperature heating step, it can be understood that the compound represented by the above formula (1-1) is contained in the cured film when heptanonitrile and benzoic acid are detected. As for the detection peak area of benzoic acid by pyrolysis gas chromatography mass spectrometry, it can be detected within a range of 1 to 10% relative to the detection peak area of heptanonitrile.

As for the pyrolysis gas chromatography mass spectrometry, it is preferable to conduct gas chromatography mass spectrometry for a gas generated by heating a measurement sample at 140° C. The heating time of the above-mentioned measurement sample may be within a range of 1 to 60 minutes. The heating time is preferably 30 minutes. One example of the measurement conditions of the pyrolysis gas chromatography mass spectrometry is given below.

### (Measurement Conditions of Pyrolysis Gas Chromatography Mass Spectrometry)

Measurement apparatus: GC/MS QP-2010 manufactured by Shimadzu Corporation, product name)
Column: HP-5MS (manufactured by Agilent Technologies Co., Ltd., product name)
Oven Temp: heated at 40° C. for 5 minutes, and the temperature was elevated to 300° C. at a rate of 15° C./min
Carrier gas: Helium, 1.0 mL/min
Interface temperature: 280° C.
Ion source temperature: 250° C.
Amount of injected sample: 0.1 mL

The content of the component (C) is preferably 0.1 to 10 parts by mass, more preferably 1 to 5 parts by mass, further preferably 1 to 3 parts by mass, and particularly preferably 1 to 2 parts by mass, relative to 100 parts by mass of the total content of the component (A) and the component (B).

In respect of further improving the rust prevention property of the protective film, it is preferred that the composition further comprise a triazole compound having a mercapto group, a tetrazole compound having a mercapto group, a thiadiazole compound having a mercapto group, a triazole compound having an amino group or a tetrazole compound having an amino group (hereinafter often referred to as the component (D)).

As the triazole compound having a mercapto group, 3-mercapto-triazole (manufactured by Wako Pure Chemical Co., Ltd., product name: 3MT) can be given. As the thiadiazole compound having a mercapto group, 2-amino-5-mercapto-1,3,4-thiazole (manufactured by Wako Pure Chemical Co., Ltd., product name: ATT) can be given, for example.

As the above-mentioned triazole compound having an amino group, benzotriazole, 1H-benzotriazole-1-acetonitrile, benzotriazole-5-carboxylic acid, 1H-benzotriazole-1-methanol, a compound obtained by substitution of an amino group with carboxybenzotriazole, etc., a compound obtained by substitution of an amino group with a triazole compound having a mercapto group such as 3-mercaptotriazole and 5-mercaptotriazole, or the like can be given.

As the above-mentioned tetrazole compound having an amino group, 5-amino-1H-tetrazole, 1-methyl-5-amino-tetrazole, 1-methyl-5-mercapto-1H-tetrazole, 1-carboxymethyl-5-amino-tetrazole, or the like can be given. These tetrazole compounds may be water-soluble salts thereof. Specific examples thereof include alkali metal salts of sodium, potassium, lithium, etc. such as 1-methyl-5-amino-tetrazole can be given.

If the composition contains the component (D), the content thereof is preferably 0.05 to 5.0 parts by mass, more preferably 0.1 to 2.0 parts by mass, further preferably 0.2 to 1.0 parts by mass, and particularly preferably 0.3 to 0.8 parts by mass, relative to 100 parts by mass of the total content of the component (A) and the component (B).

In respect of improving adhesiveness with an ITO electrode and preventing remaining after development, It is preferred that the photosensitive resin composition according to this embodiment contain a phosphoric acid ester containing a photopolymerizable unsaturated bond (hereinafter often referred to as the component (E)).

As the phosphoric acid ester containing a photopolymerizable unsaturated bond as the component (E), in respect of attaining both adhesiveness with an ITO electrode and developing property at a high level, while sufficiently ensuring rust prevention property of a protective film to be formed, Phosmer series (Phosmer-M, Phosmer-CL, Phosmer-PE, Phosmer-MH, Phosmer-PP or the like manufactured by Uni-Chemical Co., Ltd.) or KAYAMER series (PM21, PM-2 or the like, manufactured by Nippon Kayaku Co., Ltd.) are preferable.

### (High-Refractive Index Layer)

The high-refractive index layer mentioned above have a refractive index at 633 nm of preferably 1.50 to 1.90, more preferably 1.53 to 1.85, further preferably 1.55 to 1.75. By allowing the refractive index at 633 nm of the high-refractive index layer to be 1.50 to 1.90, when a laminate body shown in FIG. 2 is prepared, the refractive index becomes a value that is intermediate between a refractive index of a transparent electrode pattern 50a of ITO or the like and a refractive index of various members (e.g. OCA for adhering cover glass used for allowing it to be modular and a transparent electrode pattern) used on the photosensitive layer 20, whereby it becomes possible to decrease difference in color between a part where transparent electrode patterns (ITO, etc.) are formed and a part where transparent electrode patterns are not formed, and the “pattern visibility phenomenon” can be prevented. In addition, the intensity of reflected light of the entire screen can be decreased, whereby a decrease in the transmittance on the screen can be prevented. The refractive index can be measured with reference to the Examples of the specification.

The refractive index of the transparent electrode such as ITO is preferably 1.80 to 2.10, more preferably 1.85 to 2.05, with 1.90 to 2.00 being further preferable. In addition, the refractive index of members such as OCA is preferably 1.45 to 1.55, more preferably 1.47 to 1.53, and further preferably 1.48 to 1.51.

The thickness of the high-refractive index layer mentioned above is preferably 50 to 1000 nm, more preferably 60 to 800 nm, further preferably 70 to 600 nm, particularly preferably 80 to 500 nm, with 80 to 300 nm being significantly preferable. By allowing the film thickness to be 50 to 1000 nm, the intensity of reflected light of the entire screen mentioned above can be further decreased.

It is preferred that a high-refractive index composition constituting the high-refractive index layer 30 contain zirconium oxide, titanium oxide, a compound having a triazine ring, a compound having a fluorene skeleton or a compound having an isocyanuric acid skeleton (hereinafter referred to as the component (F)). By incorporation of this compound, the refractive index at 633 nm can be improved.

The high-refractive index composition constituting the high-refractive index layer 30 may contain the components (A) to (E), if need arises.

In respect of allowing the transparent conductive pattern to be invisible, the zirconium oxide is preferably zirconium oxide nano particles. Among zirconium oxide nano particles, those having a particle size distribution (Dmax) of 40 nm or less are preferable.

Zirconium oxide nano particles can be commercially available as OZ-S30K (product name: manufactured by Nissan Chemical Industries, Limited), OZ-S40K-AC (product name: manufactured by Nissan Chemical Industries, Limited), SZR-K (methyl ethyl ketone dispersion liquid of zirconium oxide, product name: manufactured by Nissan Chemical Industries, Limited) or SZR-M (methanol dispersion liquid of zirconium oxide, product name: manufactured by Sakai Chemical Industry Co., Ltd.) or SZR-M (methanol dispersion liquid of zirconium oxide, product name: manufactured by Sakai Chemical Industry Co., Ltd.).

In respect of allowing the transparent conductive pattern to be invisible, the titanium oxide is preferably titanium oxide nano particles. Among titanium oxide nano particles, those having a particle size distribution (Dmax) of 50 nm or less is preferable, with 10 to 50 nm being more preferable.

As the compound having an isocyanuric acid skeleton, triallyl isocyanurate is preferable. As the compound having a triazine ring, a hyper-branched polymer having a triazine ring is preferable. For example, it can be commercially available as HYPERTECH UR-101 (manufactured by Nissan Chemical Industries, Limited, product name).

As the compound having a fluorene skeleton, a compound having a 9,9-bis[4-2-(meth)acryloyloxyethoxy]phenyl]fluorene skeleton is preferable. The above compound may be modified with (poly)oxyethylene or (poly)oxypropylene. These can be commercially available as EA-200 (manufactured by Osaka Gas Chemicals Co., Ltd., product name), for example.

As for the content of the component (F) in the high-refractive index composition, in order to adjust the refractive index at 633 nm of the high-refractive index layer to be 1.5 to 1.9, the following range is preferable.

When a compound having a fluorene skeleton is contained, the content thereof is preferably 10 to 100 parts by mass, more preferably 20 to 90 parts by mass, further preferably 30 to 80 parts by mass, and particularly preferably 30 to 60 parts by mass, relative to 100 parts by mass of the high-refractive index composition.

When a compound having a triazine skeleton is contained, the content thereof is preferably 10 to 100 parts by mass, more preferably 20 to 90 parts by mass, further preferably 30 to 80 parts by mass, and particularly preferably 30 to 70 parts by mass, relative to 100 parts by mass of the high-refractive index composition.

When zirconium oxide or titanium oxide is contained, the content thereof is preferably 20 to 90 parts by mass, more preferably 30 to 80 parts by mass, and further preferably 30 to 70 parts by mass, relative to 100 parts by mass of the high-refractive index composition.

When a compound having an isocyanuric acid skeleton is contained, the content thereof is preferably 10 to 90 parts by mass, more preferably 20 to 80 parts by mass, and further preferably 30 to 70 parts by mass, relative to 100 parts by mass of the high-refractive index composition.

The minimum value of the visible ray transmittance at 400 to 700 nm of the photosensitive refractive index-adjusting transfer film is preferably 90.00% or more, more preferably 90.50% or more, and further preferably 90.70% or more. If the transmittance for visible rays with a wavelength of 400 to 700 nm (that is a common visible ray wavelength region) is 90.00% or more, when a transparent electrode in a sensing region of a touch panel (touch sensor) is protected, lowering in image display quality, shade and luminance in a sensing region can be sufficiently suppressed. The visible ray transmittance can be measured with reference to the Examples of the specification.

The photosensitive layer 20 and the high-refractive index layer 30 of the photosensitive refractive index-adjusting transfer film can be formed by preparing a coating liquid containing a photosensitive resin composition and a high-refractive index composition, and then applying this liquid respectively to the supporting film 10 and the protective film 40, followed by drying to allow them to stick to each other. Alternatively, it can be formed by applying a coating liquid containing a photosensitive resin composition on the supporting film 10, followed by drying. Thereafter, on the photosensitive layer 20, a coating liquid containing a high-refractive index composition is applied, dried, followed by sticking of the protective film 40.

The coating liquid can be obtained by uniformly dissolving or dispersing each component constituting the photosensitive resin composition and the high-refractive index composition according to the present embodiment mentioned above in a solvent.

No specific restrictions are imposed on a solvent used as a coating liquid, and known solvents can be used. Specific examples thereof include acetone, methyl ethyl ketone, methyl isobutyl ketone, toluene, methanol, ethanol, propanol, butanol, methylene glycol, ethylene glycol, propylene glycol, ethylene glycol monomethyl ether, ethylene glycol monoethyl ether, diethylene glycol dimethyl ether, diethylene glycol ethyl methyl ether, diethylene glycol diethyl ether, propylene glycol monomethyl ether, ethylene glycol monobutyl ether acetate, diethylene glycol monoethyl ether acetate, propylene glycol monomethyl ether acetate, chloroform, and methylene chloride.

As the coating method, doctor blade coating method, meyer bar coating method, roll coating method, screen coating method, spinner coating method, ink jet coating method, spray coating method, dip coating method, gravure coating method, curtain coating method, die coating method or the like can be given.

No specific restrictions are imposed on drying conditions. The drying temperature is preferably 60 to 130° C., and the drying time is preferably 0.5 to 30 minutes.

The total thickness of the photosensitive resin layer and the high-refractive index layer (hereinafter often referred to as a photosensitive refractive index-adjusting layer) is preferably 30 μm or less, more preferably 20 μm or less, and further preferably 10 μm or less, in respect of followability at the time of laminating.

The viscosity of the photosensitive refractive index-adjusting layer at 30° C. is preferably 15 to 100 mPa·s, more preferably 20 to 90 mPa·s, and further preferably 25 to 80 mPa·s, in respect of preventing a resin composition from oozing out from an end surface of a photosensitive refractive index-adjusting transfer film when storing a photosensitive refractive index-adjusting transfer film in the shape of a roll and in respect of preventing pieces of a resin composition from adhering to a substrate when a photosensitive refractive index-adjusting transfer film is cut.

As the protective film 40, propylene, polypropylene, polyethylene terephthalate, polycarbonate, a polyethylene-vinyl acetate copolymer, a laminate film of a polyethylene-vinyl acetate copolymer and polyethylene or the like can be given.

The thickness of the protective film 40 is preferably 5 to 100 μm. However, in respect of storing after rolling it in the form of a roll, the thickness thereof is preferably 70 μm or less, more preferably 60 μm or less, further preferably 50 μm or less, and particularly preferably 40 μm or less.

Next, an explanation will be made on a method for forming a cured film that satisfies both a function of protecting a transparent electrode by using a photosensitive refractive index-adjusting transfer film and both a function of allowing an electrode pattern to be invisible or improving visibility of a touch screen.

First, after removing a protective film 40 of a photosensitive refractive index-adjusting transfer film 1, the photosensitive refractive index-adjusting transfer film is crimped to the substrate surface from a high-refractive index layer 30, whereby the film is transferred to the substrate surface. As the crimping means, a crimping roll can be given. A crimping roll may be provided with a heating means so as to realize crimping with heating.

As for the heating temperature when crimping with heating is conducted, in respect of adhesiveness of the high-refractive index layer 30 and a substrate 100 and also in respect of allowing components constituting the photosensitive layer or the high-refractive index layer to be hardly cured or decomposed by heating, the heating temperature is preferably 10 to 160° C., more preferably 20 to 150° C., and further preferably 30 to 150° C.

Further, as for the crimping pressure when crimping with heating is conducted, in respect of suppressing deformation of the substrate 100 while fully ensuring adhesiveness of the high-refractive index layer 30 and the substrate 100, a linear pressure is preferably 50 to 1×10⁵ N/m, more preferably 2.5×10² to 5×10⁴ N/m, and further preferably 5×10² to 4×10⁴ N/m.

Preheating of the substrate is not necessarily required if the photosensitive refractive index-adjusting transfer film is crimped with heating as mentioned above. In respect of further improving adhesiveness between the high-refractive index layer 30 and the substrate 100, the substrate 100 may be subjected to preheating. At this time, the treatment temperature is preferably 30 to 150° C.

As the substrate, substrates such as a glass plate, a plastic plate and a ceramic plate used in a touch panel (touch sensor) can be given. On the substrate, an electrode on which a cured film is formed is provided. As the electrode, an electrode such as ITO, Cu, Al and Mo can be given. On the substrate, an insulating layer may be provided between the substrate and the electrode.

Next, a prescribed part of the transferred photosensitive refractive index-adjusting transfer layer is irradiated with active rays through a photomask. When irradiating active rays, if the supporting film 10 on the photosensitive refractive index-adjusting transfer layer is transparent, the photosensitive refractive index-adjusting transfer film is irradiated directly with active rays. If the supporting film 10 is not transparent, irradiation of active rays is conducted after removing the supporting film. As the light source of active rays, known sources of active rays can be used.

The irradiation amount of active rays is 1×10² to 1×10⁴ J/m². At the time of irradiation, heating can be simultaneously conducted. If the irradiation amount of the active rays is 1×10² J/m² or more, photo-curing can be sufficiently proceeded. If the irradiation amount is 1×10⁴ J/m² or less, discoloration of the photosensitive refractive index layer can be suppressed.

Subsequently, an unexposed part of the photosensitive layer and the high-refractive index layer after irradiation of active rays is removed by a developer, a refractive index adjusting pattern that covers part or all of the transparent electrode is formed. If the supporting film 10 is stacked on the photosensitive refractive index adjusting layer after irradiation of active rays, development is conducted after removing it.

Developing can be conducted by known methods such as spraying, showering, immersion swinging, brushing and scrapping. Among these methods, development by spraying by using an aqueous alkaline solution is preferable in respect of environment and safety. The temperature or time of developing can be adjusted within a conventionally known range.

An electronic component according to the present embodiment is provided with a refractive index-adjusting pattern formed by using a photosensitive refractive index-adjusting transfer film. As the electronic component, a touch panel, a liquid crystal display, an organic electronic luminescence device, a solar battery module, a print circuit board, electronic paper or the like can be given.

FIG. 3 is a schematic top view showing one example of a capacitive touch panel. The touch panel shown in FIG. 3 has a touch screen 102 for detecting touch position detection coordinates on one side of a transparent substrate 101. A transparent electrode 103 and a transparent electrode 104 are provided on the substrate 101 in order to detect a change in capacitance in this region. A transparent electrode 103 and a transparent electrode 104 respectively detect the X-position coordinate and the Y-position coordinate of the touch position.

On the transparent substrate 101, a lead-out wiring 105 for transmitting detected signals of the touch position from the transparent electrode 103 and the transparent electrode 104 to external circuits is provided. The lead-out wiring 105 and the transparent electrode 103 and the transparent electrode 104 are connected by a connection electrode 106 provided on the transparent electrode 103 and the transparent electrode 104. On an end part opposite to the connection part of the transparent electrode 103 and the transparent electrode 104 of the lead-out wiring 105, a connection terminal 107 for connection with external circuits is provided.

As shown in FIG. 3, by forming a refractive index adjusting pattern 123 is formed across a part where a transparent electrode pattern is formed and a part where a transparent electrode pattern is not formed, a function as a protective film of the transparent electrode 103, the transparent electrode 104, the lead-out wiring 105, the connection electrode 106 and the connection terminal 107, and a function of adjusting the refractive index of a sensing region (touch screen 102) formed of the transparent electrode pattern are simultaneously attained.

### EXAMPLES

Hereinbelow, the present invention will be explained in more detail with reference to the Examples, which should not construed as limiting the scope of the invention.

### [Preparation of a Binder Polymer Solution (A1)]

In a flask provided with a stirrer, a reflux condenser, an inert gas introduction port and a thermometer, the components (1) shown in Table 1 were charged, and heated to 80° C. in a nitrogen gas atmosphere. While keeping the reaction temperature to 80° C.±2° C., the component (2) shown in Table 1 was added dropwise homogenously for 4 hours. After dropwise addition of the component (2), stirring was conducted at 80° C.±2° C. for 6 hours, whereby a solution (solid matter content: 45 mass %) of a binder polymer having a weight-average molecular weight of 65,000, an acid value of 78 mgKOH/g and a hydroxyl value of 2 mgKOH/g was obtained (A1).

TABLE 1

| | | Blended Amount |
|---|---|---|
| | | (parts by mass) |
| | | (A1) |
| (1) | Propylene glycol monomethyl ether | 62 |
| | Toluene | 62 |
| (2) | Methacrylic acid | 12 |
| | Methyl methacrylate | 58 |
| | Ethyl acrylate | 30 |
| | 2,2′-azobis (isobutylonitrile) | 1.5 |

| | |
|---|---|
| Weight-average molecular weight | 65,000 |
| Hydroxyl value (mgKOH/g) | 2 |
| Acid value (mgKOH/g) | 78 |
| Tg (° C.) | 60 |

The weight-average molecular weight (Mw) was measured by gel permeation chromatography (GPC) and converted by a calibration line of standard polystyrene. Conditions of GPC are shown below.

### <GPC Conditions>

Pump: L-6000 (manufactured by Hitachi, Ltd., product name)

Column: Gelpack GL-R420, Gelpack GL-R430, Gelpact GL-R440, all are manufactured by Hitachi Chemical Co., Ltd., product name)

Eluent: Tetrahydrofuran

Measurement temperature: 40° C.

Flow rate: 2.05 ml/min

Detector: L-3300 (RI detector, manufactured by Hitachi, Ltd., product name)

### [Method for Measuring Acid Value]

The binder polymer solution was heated at 130° C. for 1 hour, and volatile matters were removed to obtain solid matters. Then, 1 g of the solid polymer was preciously weighed. 30 g of acetone was added to this polymer, and the polymer was uniformly dissolved therein. Subsequently, an appropriate amount of phenolphthalein as an indicator was added thereto, and titration was conducted by using a 0.1N KOH aqueous solution. An acid value was calculated by the following formula:

Acid value: 0.1×Vf×56.1/(Wp×I/100)

In the formula, Vf shows a titration amount (mL) of an aqueous solution of KOH, Wp is a mass (g) of the resin solution measured, and I is a ratio (mass %) of non-volatile matters in the resin solution measured.

### [Method for Measuring Hydroxyl Value]

The binder polymer solution was heated at 130° C. for 1 hour, and volatile matters were removed to obtain solid matters. 1 g of the solid matters were preciously weighed, and the polymer was put in an Erlenmeyer flask. 10 mL of a 10 mass % anhydrous acetic pyridine solution was added, and heated at 100° C. for 1 hour. After the heating, 10 mL of water and 10 mL of pyridine were added, and heated at 100° C. for 10 minutes. Thereafter, by using an automatic titrator (manufactured by Hiranuma Sangyo Co., Ltd., product name: COM-1700), neutralization titration was conducted with 0.5 mol/L of an ethanol solution of potassium hydroxide. The hydroxy value was calculated by the following formula:

Hydroxy value=(A−B)×f×28.05/sample(g)+acid value

In the formula, A is the amount (mL) of the 0.5 mol/L-ethanol solution of potassium hydroxide used for a blank test, B is the amount (mL) of the 0.5 mol/L-ethanol solution of potassium hydroxide used for titration and f is a factor.

### Examples 1 to 16 and Comparative Examples 1 to 6

### [Preparation of Coating Liquid for Forming Photosensitive Layer]

The composition A and the composition B shown in Table 2 were mixed for 15 minutes by using a stirrer, whereby a coating liquid for forming a photosensitive layer was prepared.

TABLE 2

| Item | | Composition A | Composition B |
|---|---|---|---|
| Component (A) | A1 | 16 | 60 |
| Component (B) | T-1420 (T) | 40 | 40 |
| Component (C) | IRGACURE OXE 01 | 1.7 | 1.7 |
| Component (D) | HAT | 0.4 | 0.4 |
| Component (E) | PM-21 | 0.5 | 0.25 |
| Others | Antage W-500 | 0.1 | 0.1 |
| | SH-30 | 0.07 | 0.07 |
| | Methyl ethyl ketone | 50 | 50 |

The symbols for the components in Table 2 have the following meaning. Component (A)

(A1): A propylene glycol monomethyl ether/toluene solution of a copolymer having a monomer blending ratio (methacrylic acid/methyl methacrylate/ethyl acrylate=12/58/30 (mass ratio)), weight-average molecular weight 65,000, acid value 78 mgKOH/g, hydroxyl value 2 mgKOH/g, Tg 60° C.

### Component (B)

T-1420 (T): Ditrimethylol propane tetracrylate (manufactured by Nippon Kayaku Co., Ltd., product name)

### Component (C)

IRGACURE OXE 01: 1,2-octanediane, 1-[(4-phenylthio)phenyl, 2-(O-benzoyloxime)](manufactured by BASF Japan Ltd., product name)

### Component (D)

HAT: 5-amino-1H-tetrazole (manufactured by Toyobo Co., Ltd., product name)

### Component (E)

PM-21: Phosphoric acid ester including a photopolymerizable unsaturated bond (manufactured by Nippon Kayaku Co., Ltd., product name)

### Other Components

Antage W-500: 2,2′-methylene-bis(4-ethyl-6-tert-butylphenol) (manufactured by Kawaguchi Chemical Industry Co., Ltd., product name)
SH-30: Octamethylcyclotetrasiloxane (manufactured by Dow Corning Toray Co., Ltd., product name)
Methyl ethyl ketone (manufactured by Tonen Chemical Corporation)

### [Preparation of Coating Film for Forming High-Refractive Layer]

The components in the “high-refractive layer” in Table 3 and Table 4 were mixed for 15 minutes by means of a stirrer, whereby a coating liquid for forming a high-refractive layer was prepared.

TABLE 3

| | | | Examples | | | | | | | | | | | | | |
|---|---|---|---|---|---|---|---|---|---|---|---|---|---|---|---|---|
| Item | | | 1 | 2 | 3 | 4 | 5 | 6 | 7 | 8 | 9 | 10 | 11 | 12 | 13 | 14 |
| Photosensitive layer | | | A | A | A | B | B | B | B | B | A | A | A | A | A | A |
| High- | Component (F) | UR101 | 50 | 50 | 50 | 50 | 50 | 50 | 50 | 50 | 50 | 50 | — | — | — | — |
| refractive | | OZ-S40K-AC | — | — | — | — | — | — | — | — | — | — | 65 | 40 | 65 | 50 |
| layer | | OZ-S30K | — | — | — | — | — | — | — | — | — | — | — | — | — | — |
| | | EA-200 | — | — | — | — | — | — | — | — | — | — | 35 | 60 | — | — |
| | | EA-F5503 | 50 | 50 | 50 | 50 | 50 | 50 | 50 | 50 | 50 | 50 | — | — | — | — |
| | | EA-HC931 | — | — | — | — | — | — | — | — | — | — | — | — | 35 | 50 |
| | Others | AW500 | — | — | — | — | — | — | — | — | — | — | — | — | — | — |
| | | L-7001 | 1 | 1 | 1 | 1 | 1 | 1 | 1 | 1 | 1 | 1 | — | — | — | — |

The symbols in Table 3 and Table 4 have the following meaning.

### Component (F)

UR101: Polymer having a triazine skeleton (manufactured by Nissan Chemical Industries, Inc., product name: HYPERTECH (trade name))
OZ-S40K-AC: Zirconia dispersion liquid (manufactured by Nissan Chemical Industries, Ltd., product name: NanoUse OZ-S40K-AC)
OZ-S30K: Zirconia dispersion liquid (manufactured by Nissan Chemical Industries, Ltd., product name: NanoUse OZ-S30 K)
EA-200: Polyoxyethylene-modified 9,9-bis(4-hydroxyphenyl)fluorenediacrylate (manufactured by Osaka Gas Chemical Co., Ltd., product name)
EA-F 5503: Mixture of polyoxyethylene-modified 9,9-bis(4-hydroxyphenyl) fluorenediacrylate/benzyl acrylate/9,9-bis (4-hydroxyphenyl) fluorene skeleton compound (manufactured by Osaka Gas Chemicals Co., Ltd., product name)
EA-HC 931: Mixture of polyoxyethylene-modified 9,9-bis(4-hydroxyphenyl) fluorenediacrylate and others (manufactured by Osaka Gas Chemicals Co., Ltd., product name)
L-7001: Octamethylcyclotetrasiloxane (manufactured by Dow Corning Toray Co., Ltd., product name)

TABLE 4

| | | | Examples | | Comparative Examples | | | |
|---|---|---|---|---|---|---|---|---|
| Item | | | 15 | 16 | 3 | 4 | 5 | 6 |
| Photosensitive layer | | | A | A | — | — | — | — |
| High- | Component (A) | A1 | 30 | 10 | 30 | 10 | 60 | 60 |
| refractive | Component (B) | T-1420(T) | — | — | — | — | 40 | 40 |
| layer | Component (C) | IRGACURE OXE 01 | 1.7 | 1.7 | 1.7 | 1.7 | 1.7 | 1.7 |
| | Component (D) | HAT | — | 0.4 | — | 0.4 | 0.4 | 0.4 |
| | | 3MT | 1.0 | — | 1.0 | — | — | — |
| | Component (E) | PM-21 | 0.25 | — | 0.25 | — | 0.25 | 0.25 |
| | | Phosmer_M | — | 2.0 | — | 2.0 | — | — |
| | Component (F) | UR101 | — | — | — | — | — | — |
| | | OZ-S40K-AC | 102.5 | 193.64 | 102.5 | 193.64 | — | — |
| | | OZ-S30K | — | — | — | — | 102.5 | 190.4 |
| | | EA-200 | 50 | 50 | 50 | 50 | — | — |
| | | EA-F5503 | — | — | — | — | — | — |
| | | EA-HC931 | 20 | 40 | 20 | 40 | — | — |
| | Others | AW500 | 0.1 | 0.1 | 0.1 | 0.1 | 0.1 | 0.1 |
| | | L-7001 | 0.07 | 0.07 | 0.07 | 0.07 | 0.07 | 0.07 |

### Component (D)

3MT: 3-Mercapto-triazole (manufactured by Wako Pure Chemical Industries, product name)

### [Measurement of Refractive Index]

A coating liquid for forming the high-refractive layer prepared above was uniformly applied onto a 0.7 mm-thick glass substrate by means of a spin coater, and dried by a hot air convention drier of 100° C. for 3 minutes to remove the solvent, whereby a high-refractive layer was formed.

Subsequently, the high-refractive layer obtained above was irradiated with ultraviolet rays with an exposure amount of 5×10² J/m² (measured value at 365 nm) by using a parallel light exposure apparatus (EXM1201 manufactured by Orc Manufacturing Co., Ltd.). Then, the layer was left in a box-type dryer (model: NV50-CA manufactured by Mitsubishi Electric Corporation) at 140° C. for 30 minutes, whereby a sample having the high-refractive layer for measuring the refractive index was obtained. In Examples 1 to 14 where the component (C) was not contained in the high-refractive layer, the exposure step was omitted.

Subsequently, for the obtained sample for measuring the refractive index, the refractive index at 633 nm was measured by means of ETA-TCM (manufactured by AudioDev GmbH). In the meantime, in the form of a photosensitive refractive index-adjusting transfer film, it is difficult to measure the refractive index of the refractive index layer alone. Therefore, the refractive index is a refractive index value of the outermost layer on the side of the supporting film of the high-refractive layer.

### [Preparation of Photosensitive Refractive Index Adjusting Transfer Film]

As the protective film, a 30 μm-thick polyethylene terephthalate film (manufactured by Oji F-Tex Co., Ltd, product name: E-201F) was used. The coating liquid prepared above for forming the high-refractive layer was uniformly applied onto a protective film by using a die coater, and dried for 3 minutes in a hot air convection drier of 100° C. to remove the solvent, whereby a high-refractive layer was formed.

As the supporting film, a 16 μm-thick polyethylene terephthalate film (manufactured by Toray Industries, Inc., product name: FB40) was used. The coating liquid prepared above for forming the photosensitive layer was uniformly applied onto a protective film by using a comma coater, and dried for 3 minutes in a hot air convection drier of 100° C. to remove the solvent, whereby an 8 μm-thick photosensitive layer was formed.

### [Measurement of Thickness of High-Refractive Layer and Photosensitive Layer]

The thickness of the high-refractive layer formed on the 30 μm-thick polypropylene film prepared above was measured by means of F20 (manufactured by FILMMETRIC Inc., product name).

Further, the thickness of the photosensitive layer formed on a 16 μm-thick polyethylene terephthalate film prepared above was measured by means of a digital thickness gauge (manufactured by Nikon Corporation, product name: DIGIMIRCOSTAND MS-5C).

Subsequently, the obtained protective film having the high-refractive layer and the obtained supporting film having the photosensitive layer were laminated by means of a laminator (manufactured by Hitachi Chemical Co., Ltd. product name: HLM-3000) at 23° C., whereby a photosensitive refractive index-adjusting transfer film was prepared.

### [Measurement of Transmittance and Haze of Cured Film]

While peeling off the protective film of the photosensitive refractive index-adjusting transfer film prepared above, on a 0.7 mm-thick glass substrate, lamination was conducted by using a laminator (manufactured by Hitachi Chemical Co., Ltd., product name: HLM-3000) such that the high-refractive layer was brought into contact therewith under conditions of roll temperature of 120° C., substrate supply speed of 1 m/min and crimping pressure (cylinder pressure) of 4×10⁵ Pa (since a substrate having a thickness of 1 mm and a vertical length of 10 cm and a lateral length of 10 cm was used, the linear pressure at the time of the lamination was 9.8×10³ N/m), whereby a laminate body in which the high-refractive layer, the photosensitive layer and the supporting film were stacked on the glass substrate was prepared.

Subsequently, the obtained laminate body was irradiated with UV rays by means of a parallel ray exposure apparatus (product name: EXM1201, manufactured by Oak Manufacturing Co., Ltd.) from the upper side of the photosensitive layer with an exposure amount of 5×10² J/m² (measured value at a wavelength of 365 nm). Thereafter, the supporting film was removed, and left for 30 minutes at 140° C. in a box-type dryer (model: NV50-CA, manufactured by Mitsubishi Electric Corporation), whereby a sample for measuring the transmittance was obtained.

Subsequently, for the obtained sample for measuring the transmittance, visible ray transmittance and haze value were measured at a measurement wavelength region of 400 to 700 nm by means of a haze meter (product name: NDH 7000, manufactured by Nippon Denshoku Industries, Co., Ltd.). The results obtained are shown in Tables 5 to 7.

### [Salt Water Spray Test (Test for Resistance to Artificial Sweat)]

While peeling off the protective film of the photosensitive refractive index-adjusting transfer film prepared above, on a polyimide film provided with copper for sputtering (manufactured by Toray Advanced Film Co., Ltd.), lamination was conducted by using a laminator (manufactured by Hitachi Chemical Co., Ltd. product name: HLM-3000) such that the high-refractive layer was brought into contact therewith under conditions of roll temperature of 120° C., substrate supply speed of 1 m/min and crimping pressure (cylinder pressure) of 4×10⁵ Pa (since a substrate having a thickness of 1 mm and a vertical length of 10 cm and a lateral length of 10 cm was used, the linear pressure at the time of the lamination was 9.8×10³ N/m), whereby a laminate body in which the high-refractive layer, the photosensitive layer and the supporting film were stacked was obtained.

Subsequently, the photosensitive layer of the obtained laminate body was irradiated with UV rays by means of a parallel ray exposure apparatus (manufactured by Oak Manufacturing Co., Ltd., product name: EXM1201) from the upper side of the photosensitive layer with an exposure amount of 5×10² J/m² (measured value at a wavelength of 365 nm). Thereafter, the supporting film was removed, and the layer was further irradiated with UV rays from the upper side of the photosensitive layer with an exposure amount of 1×10⁴ J/m² (measured value at a wavelength of 365 nm). Then, the layer was left for 30 minutes at 140° C. in a box-type dryer (manufactured by Mitsubishi Electric Corporation, model: NV50-CA), whereby a sample for evaluating the resistance to artificial sweat was obtained.

Subsequently, in accordance with JIS standards (Z 2371), by using a salt water spray tester (manufactured Suga Test Instrument Co., Ltd., product name: STP-90V2), the sample mentioned above was placed in a test chamber, and salt water having a concentration of 50 g/L (pH=6.7) was sprayed for 48 hours at a test chamber temperature of 35° C. and a spray amount of 1.5 mL/h. After completion of the spraying, the salt water was wiped off, and the surface condition of the sample for evaluation was observed, and evaluated in accordance with the following points. The measurement results are shown in Tables 5 to 7.

A: No change was observed on the surface of the protective film

B: Slight marks were observed on the surface of the protective film, but no change was observed in the copper

C: Slight marks were observed on the surface of the protective film

D: Marks were observed on the surface of the protective film, and the copper was underwent discoloration

### [Measurement of Hue (Reflectance R)]

While peeling off the protective film of the obtained photosensitive refractive index-adjusting transfer film, on a transparent conductive film (manufactured by Toyobo Co., Ltd., product name: 300R), lamination was conducted by using a laminator (manufactured by Hitachi Chemical Co., Ltd., product name: HLM-3000) such that the high-refractive layer was brought into contact therewith under conditions of roll temperature of 120° C., substrate supply speed of 1 m/min and crimping pressure (cylinder pressure) of 4×10⁵ Pa (since a substrate having a thickness of 1 mm and a vertical length of 10 cm and a lateral length of 10 cm was used, the linear pressure at the time of the lamination was 9.8×10³ N/m), whereby a laminate body in which the high-refractive layer, the photosensitive layer and the supporting film were stacked on the glass substrate was obtained.

Subsequently, the obtained laminate body was irradiated with UV rays by means of a parallel ray exposure apparatus (manufactured by Oak Manufacturing Co., Ltd., product name: EXM1201) from the upper side of the photosensitive layer with an exposure amount of 5×10² J/m² (measured value at a wavelength of 365 nm). Thereafter, the supporting film was removed, whereby a sample for measuring a hue (reflectance R) having a cured film was obtained.

Subsequently, by using a spectral colorimeter (manufactured by Konica Minolta, product name: CM-5), the Y value (this is taken as the reflectance index R) of the obtained sample for measuring hue (reflectance R) was measured, and standardization was conducted by using the following formula:

Standardization of the reflectance R=Actual measured value of the reflectance/Actual measured value of the reflectance of the measurement sample in which only the photosensitive layer was laminated(Comparative Example 2)×100

TABLE 5

| | Examples | | | | | | | |
|---|---|---|---|---|---|---|---|---|
| Item | 1 | 2 | 3 | 4 | 5 | 6 | 7 | 8 |
| Refractive index@633 | 1.615 | 1.615 | 1.615 | 1.615 | 1.615 | 1.615 | 1.615 | 1.615 |
| High-refractive layer thickness (nm) | 90 | 100 | 110 | 125 | 140 | 175 | 185 | 195 |
| Photosensitive layer thickness (μm) | 8 | 8 | 8 | 8 | 8 | 8 | 8 | 8 |
| Y Value | 8.55 | 8.495 | 8.245 | 8.185 | 7.965 | 7.595 | 7.665 | 7.695 |
| Salt water spray test | A | A | A | A | A | A | A | A |
| Transmittance (%) | 90.72 | 90.82 | 91.01 | 91.07 | 91.29 | 91.59 | 91.45 | 91.48 |
| Haze | 0.47 | 0.38 | 0.65 | 0.75 | 0.60 | 0.49 | 0.39 | 0.44 |
| Reflectance (R) standardization | 89.8% | 89.2% | 86.6% | 85.9% | 83.6% | 79.7% | 80.5% | 80.8% |

TABLE 6

| | Examples | | | | | | | |
|---|---|---|---|---|---|---|---|---|
| Item | 9 | 10 | 11 | 12 | 13 | 14 | 15 | 16 |
| Refractive index@633 | 1.615 | 1.615 | 1.646 | 1.615 | 1.632 | 1.630 | 1.621 | 1.651 |
| High-refractive layer thickness (nm) | 205 | 220 | 220 | 220 | 220 | 220 | 220 | 220 |
| Photosensitive layer thickness (μm) | 8 | 8 | 8 | 8 | 8 | 8 | 8 | 8 |
| Y Value | 7.68 | 7.695 | 7.77 | 8.035 | 7.78 | 8 | 7.82 | 8.08 |
| Salt water spray test | A | A | A | A | A | A | A | A |
| Transmittance (%) | 91.54 | 91.26 | 91.35 | 91.10 | 91.30 | 91.16 | 90.71 | 90.75 |
| Haze | 0.55 | 0.60 | 0.33 | 0.37 | 0.37 | 0.38 | 0.80 | 0.82 |
| Reflectance (R) standardization | 80.6% | 80.8% | 81.6% | 84.4% | 81.7% | 84.0% | 82.1% | 84.8% |

TABLE 7

| | Comparative Examples | | | | | |
|---|---|---|---|---|---|---|
| Item | 1 | 2 | 3 | 4 | 5 | 6 |
| Refractive index@633 | — | 1.474 | 1.621 | 1.651 | 1.556 | 1.582 |
| High-refractive layer thickness (nm) | — | 0 | 8000 | 8000 | 8000 | 8000 |
| Photosensitive layer thickness (μm) | — | 8 | 0 | 0 | 0 | 0 |
| Y Value | 16.81 | 9.525 | 9.16 | 9.03 | 9.28 | 8.94 |
| Salt water spray test | D | A | C | C | C | C |
| Transmittance (%) | 82.60 | 89.85 | 90.21 | 90.52 | 89.93 | 90.25 |
| Haze | 1.56 | 1.03 | 1.17 | 1.16 | 1.10 | 1.32 |
| Reflectance (R) standardization | 176.5% | 100.0% | 96.2% | 94.8% | 97.4% | 93.9% |

As shown in Tables 5 to 7, in the Examples, the standardization value of R (reflectance) became 90% or less, i.e. the reflectance was sufficiently reduced. Further, the resistance to the salt water spray was also sufficient. Comparative Example 1 shows the result where neither the photosensitive layer nor the high-refractive layer was provided, and Comparative Example 2 shows the result where only the photosensitive layer was provided.

### EXPLANATION OF REFERENTIAL NUMERALS

1. Photosensitive refractive index-adjusting transfer film
10. Supporting film
20. Photosensitive resin layer
30. High-refractive index layer
40. Protective film
50. Substrate with transparent conductive pattern
50a. Transparent conductive pattern
100. Laminated body
101. Transparent substrate
102. Sensing region
103, 104. Transparent electrode
105. Lead-out wiring
106. Connection electrode
107. Connection terminal
123. Refractive index-adjusting pattern

1. A photosensitive refractive index-adjusting transfer film comprising a supporting film, a photosensitive resin layer provided on the supporting film, and a high-refractive index layer provided on the photosensitive resin layer.

2. The photosensitive refractive index-adjusting transfer film according to claim 1, wherein the refractive index at 633 nm of the high-refractive index layer is 1.5 to 1.9.

3. The photosensitive refractive index-adjusting transfer film according to claim 1, wherein the thickness of the high-refractive index layer is 0.05 to 1 μm.

4. The photosensitive refractive index-adjusting transfer film according to claim 1, wherein the high-refractive index layer comprises zirconium oxide, titanium oxide, a compound having a triazine ring, a compound having a fluorene skeleton or a compound having an isocyanuric acid skeleton.

5. The photosensitive refractive index-adjusting transfer film according to claim 1 wherein the photosensitive resin layer comprises a binder polymer, a photopolymerizable compound and a photopolymerization initiator.

6. The photosensitive refractive index-adjusting transfer film according to claim 5, wherein the photopolymerization initiator comprises an oxime ester compound.

7. The photosensitive refractive index-adjusting transfer film according to claim 5, wherein the binder polymer comprises a carboxyl group.

8. The photosensitive refractive index-adjusting transfer film according to claim 1, wherein the minimum value of the visible ray transmittance at 400 to 700 nm is 90% or more.

9. The photosensitive refractive index-adjusting transfer film according to claim 1, wherein the total thickness of the photosensitive resin layer and the high-refractive index layer is 30 μm or less.

10. A method for forming a refractive index-adjusting pattern, comprising:
a step of laminating the high-refractive index layer and the photosensitive resin layer of the photosensitive refractive index-adjusting transfer film according to claim 1 on a substrate such that the high-refractive index layer is brought into close contact with the substrate; and
a step of exposing prescribed parts of the high-refractive index layer and the photosensitive resin layer on the substrate, and removing parts other than the prescribed parts, thereby to form a refractive index-adjusting pattern.

11. An electronic component having a refractive index-adjusting pattern that is obtained by the method according to claim 10.
